(19) United States
(12) Patent Application Publication
(10) Pub. No.: US 2019/0165761 A1
(43) Pub. Date: May 30, 2019

(54) TUNING-FORK TYPE QUARTZ CRYSTAL VIBRATING ELEMENT AND PIEZOELECTRIC DEVICE

(71) Applicant: KYOCERA Corporation, Kyoto-shi (JP)

(72) Inventors: Takahiro OGA, Kyoto-shi (JP); Hitoshi YOSHIDA, Kyoto-shi (JP)

(73) Assignee: KYOCERA Corporation, Kyoto-shi (JP)

(21) Appl. No.: 16/201,474

(22) Filed: Nov. 27, 2018

(30) Foreign Application Priority Data
Nov. 28, 2017 (JP) 2017-227953

(51) Int. Cl. H03H 9/215; H03H 9/05; H03H 9/10

(52) U.S. Cl. CPC H03H 9/215; H03H 9/1021; H03H 9/0519

(57) ABSTRACT

To provide a tuning-fork type quartz crystal vibrating element capable of decreasing changes in oscillation frequencies before and after being mounted. The tuning fork element includes: a base part; a pair of vibration arm parts extended in a same longitudinal direction from the base part; and respective weight parts located at the tips of the vibration arm parts. Provided that, on a plan view, a measurement in the longitudinal direction is length, and a measurement in a direction perpendicular to the longitudinal direction is width, Expression (1) −100≤x≤100, −30≤y≤30, and −0.3x−15≤y≤−0.3x+15 applies, where a difference between the length of the vibration arm parts together with the respective weight parts and the reference value x₀ is x, a difference between the width of the weight parts and the reference value y₀ is y, and the unit is μm.

This application claims priority to and the benefit of Japanese Patent Application No. 2017-227953 filed on Nov. 28, 2017, the entire contents of which are incorporated herein by reference.

### BACKGROUND OF THE INVENTION

### 1. Field of the Invention

The present disclosure relates to a tuning-fork type quartz crystal vibrating element (referred to as “a tuning fork element” hereinafter) used for a reference signal source or a clock signal source and to a piezoelectric device to which the same is mounted.

### 2. Description of the Related Art

A tuning fork element of a related technique includes a base part, a pair of vibration arm parts extended from the base part in a same longitudinal direction, and respective weight parts located at tips of the vibration arm parts (see Japanese Unexamined Patent Application Publication No. 2017-98765). Further, the vibration arm parts include grooves, and the grooves include excitation electrodes on the inner side and outer side thereof. Since the vibration arm parts have the respective weight parts at their tips, it is possible with the tuning fork element to lower the frequency of the bending vibration while keeping the vibration arm parts short. Therefore, the tuning fork element can be downsized. Further, voltages can be applied to the vibration arm parts by the excitation electrodes provided on the inner side and outer side of the grooves.

### SUMMARY OF THE INVENTION

A tuning-fork type quartz crystal vibrating element according to an exemplary embodiment of the present disclosure includes: a base part; a pair of vibration arm parts extended in a same longitudinal direction from the base part; and respective weight parts located at tips of the vibration arm parts, wherein provided that, on a plan view, a measurement in the longitudinal direction is defined as length, a measurement in a direction perpendicular to the longitudinal direction is defined as width, a reference value of the length of the vibration arm parts together with the respective weight parts is defined as x₀, and a reference value of the width of the weight parts is defined as y₀, following Expression (1) applies, where a difference between the length of the vibration arm parts together with the respective weight parts and the reference value x₀ is x, a difference between the width of the weight parts and the reference value y₀ is y, and a unit is μm.

−100≤x≤100,

−30≤y≤30, and

−0.3x−15≤y≤−0.3x+15 (1)

With an exemplary embodiment of the present disclosure, it is possible to decrease changes in the oscillation frequency before and after mounting the tuning fork element through improving the relation between the length of the vibration arm parts together with the respective weight parts and the width of the weight parts.

### BRIEF DESCRIPTION OF THE DRAWINGS

FIG. 1 is a plan view showing a tuning fork element of an exemplary embodiment;

FIG. 2A is a sectional view taken along a line IIa-IIa of FIG. 1, and FIG. 2B is a schematic sectional view showing a piezoelectric device having the tuning fork element of FIG. 1 mounted thereon;

FIG. 3 is a plan view showing examples of main measurements of the tuning fork element shown in FIG. 1;

FIGS. 4A to 4F are schematic plan views showing vibration modes of the tuning fork element of FIG. 1, in which FIG. 4A is an in-phase mode, FIG. 4B is a principal vibration mode, FIG. 4C is a dolphin mode, FIG. 4D is a flutter-kick mode, FIG. 4E is a torsion (in-phase) mode, and FIG. 4F is a torsion (reversed-phase) mode;

FIG. 5A is a chart showing “free-fix” when the arm length x and the weight width y are changed;

FIG. 5B is a graph showing the relations regarding the arm length x, the weight width y, and the free fix;

FIG. 6A is a chart showing frequencies of each vibration mode when the arm length x is changed while keeping the weight width y as 0, FIG. 6B is a graph showing the relation between the arm length x and the frequencies of each vibration mode shown in FIG. 6A, and FIG. 6C is a graph showing the relation regarding the arm length x, the free-fix, and the in-phase difference shown in FIG. 6A;

FIG. 7A is a chart showing the frequencies of each vibration mode and the like when the weight width y is changed while keeping the arm length x as 0, FIG. 7B is a graph showing the relation between the weight width y and the frequencies of each vibration mode shown in FIG. 7A, and FIG. 7C is a graph showing the relation regarding the weight width y, the free-fix, and the in-phase difference shown in FIG. 7A;

FIG. 8A is a chart showing frequencies of each vibration mode when the arm length x is changed while keeping the weight width y as −30, FIG. 8B is a graph showing the relation between the arm length x and the frequencies of each vibration mode shown in FIG. 8A, and FIG. 8C is a graph showing the relation regarding the arm length x, the free-fix, and the in-phase difference shown in FIG. 8A;

FIG. 9A is a chart showing frequencies of each vibration mode when the arm length x is changed while keeping the weight width y as −15, FIG. 9B is a graph showing the relation between the arm length x and the frequencies of each vibration mode shown in FIG. 9A, and FIG. 9C is a graph showing the relation regarding the arm length x, the free-fix, and the in-phase difference shown in FIG. 9A;

FIG. 10A is a chart showing frequencies of each vibration mode when the arm length x is changed while keeping the weight width y as +15, FIG. 10B is a graph showing the relation between the arm length x and the frequencies of each vibration mode shown in FIG. 10A, and FIG. 10C is a graph showing the relation regarding the arm length x, the free-fix, and the in-phase difference shown in FIG. 10A; and

FIG. 11A is a chart showing frequencies of each vibration mode when the arm length x is changed while keeping the weight width y as +30, FIG. 11B is a graph showing the relation between the arm length x and the frequencies of each vibration mode shown in FIG. 11A, and FIG. 11C is a graph showing the relation regarding the arm length x, the free-fix, and the in-phase difference shown in FIG. 11A.

### DETAILED DESCRIPTION OF THE EMBODIMENTS

The tuning fork element of the related technique includes the respective weight parts at the free ends (tips) of the vibration arm parts. Thus, when an alternating voltage is applied to an excitation electrode, secondary vibrations also tend to occur other than the principal vibration of a reversed-phase mode. The secondary vibrations include at least one of a vibration of an in-phase mode, a vibration of a torsion mode, a vibration called “dolphin” described later, and a vibration called “flutter kick” described later. Such tendency is particularly strong in a small tuning fork element whose total length is 1200 μm or smaller. Thus, when the tuning fork element is mounted on an element loading member (package), the base part is distorted by a change in the stress from the element loading member and the secondary vibration becomes greater due to the distortion. As a result, the oscillation frequency becomes changed before and after mounting the tuning fork element of the related technique, so that it is difficult to acquire the oscillation frequency as designed.

The inventors have acquired following findings as a result of repeatedly conducted researches and experiments on the tuning fork element of the related technique having the respective weight parts at the tips of the vibration arm parts in order to decrease changes in the oscillation frequency before and after being mounted.

In simulation experiments of the tuning fork element, it was found that changes in the oscillation frequency before and after being mounted are decreased when there is a specific relation between the length of the vibration arm parts together with the respective weight parts and the width of the weight parts.

Modes for embodying the present disclosure (referred to as “exemplary embodiments” hereinafter) will be described hereinafter by referring to the accompanying drawings. In the description and drawings, same reference numerals are used for substantially same structural elements. Further, drawings are not necessarily to scale for the easy of understanding by those skilled in the art, so that measurements and ratios of any shape illustrated in the drawings are not necessarily consistent with the actual ones.

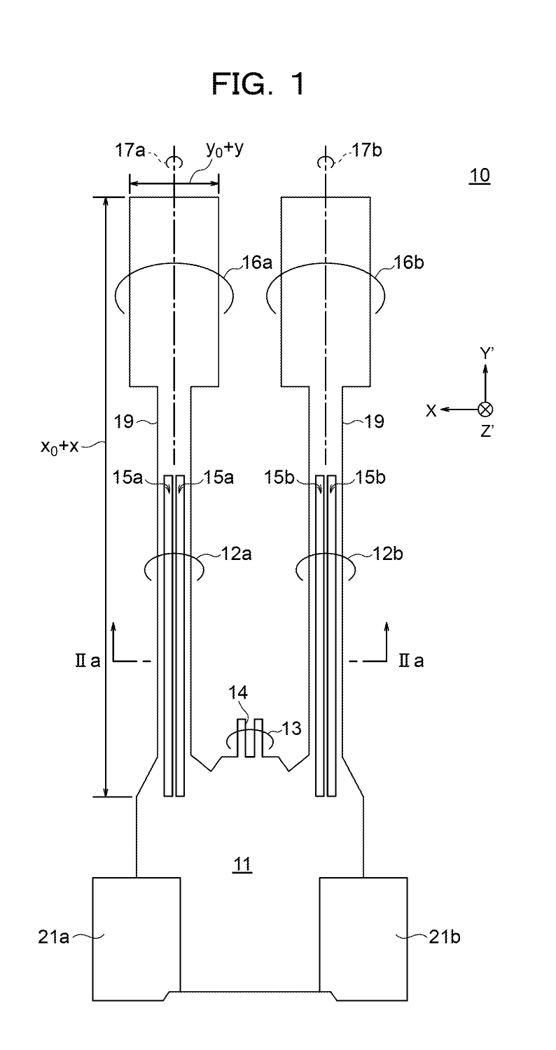

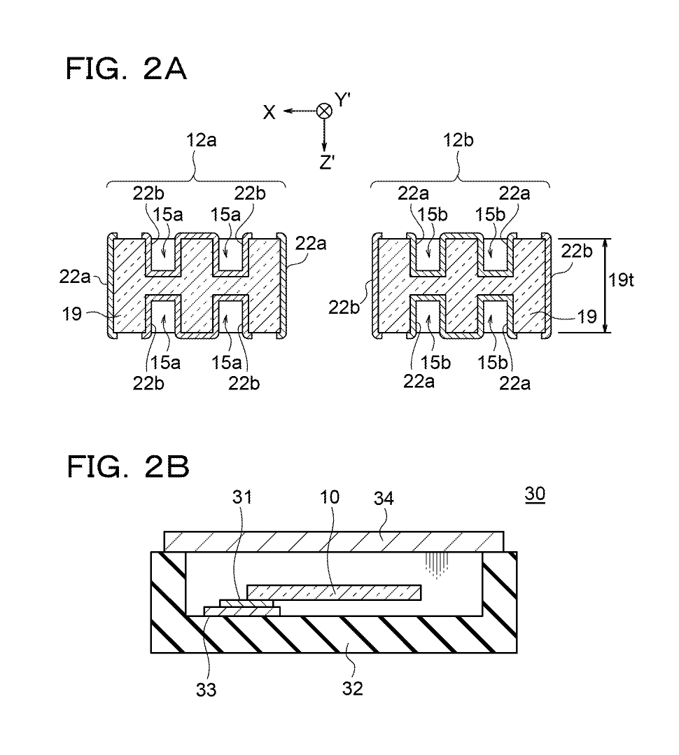

FIG. 1 is a plan view showing a tuning fork element of an exemplary embodiment. FIG. 2A is a sectional view taken along a line IIa-IIa of FIG. 1, and FIG. 2B is a schematic sectional view showing a piezoelectric device having the tuning fork element of FIG. 1 mounted thereon. Hereinafter, the exemplary embodiment will be described by referring to those drawings.

As shown in FIG. 1 and FIG. 2A, a tuning fork element 10 according to an exemplary embodiment includes: a base part 11; a pair of vibration arm parts 12a, 12b extended in a same longitudinal direction (Y′-axis direction) from the base part 11; and respective weight parts 16a and 16b located at the tips of the vibration arm parts 12a, 12b. Provided that, on a plan view, the measurement in the longitudinal direction (Y′-axis direction) is defined as length, the measurement in a direction (X-axis direction) perpendicular to the longitudinal direction (Y′-axis direction) is defined as width, a reference value of the length of the vibration arm parts 12a, 12b together with the respective weight parts 16a, 16b is defined as x₀, and a reference value of the width of the weight parts 16a, 16b is defined as y₀, following Expression (1) applies, where a difference between the length of the vibration arm parts 12a, 12b together with the respective weight parts 16a, 16b and the reference value x₀ is x, a difference between the width of the weight parts 16a, 16b and the reference value y₀ is y, and the unit is μm.

−100≤x≤100,

−30≤y≤30, and

−0.3x−15≤y≤−0.3x+15 (1)

With the tuning fork element 10 of the exemplary embodiment, changes in the oscillation frequency before and after being mounted can be decreased through improving the relation between the length of the vibration arm parts 12a, 12b together with the respective weight parts 16a, 16b and the width of the weight parts 16a, 16b (details thereof will be described later).

Also, following Expression (2) may apply instead of Expression (1).

−100≤x≤100,

−30≤y≤30, and

y=−0.3x (2)

In this case, changes in the oscillation frequency before and after being mounted can be decreased more.

Further, it may also be defined that x and y in Expression (1) or Expression (2) satisfy following Expression (3).

−50≤x≤50, and −15≤y≤15 (3)

In this case, changes in the oscillation frequency before and after being mounted can be decreased even more.

Furthermore, such effect of decreasing changes in the oscillation frequency before and after being mounted becomes prominent when the reference value x₀ is 780 μm and the reference value y₀ is 102 μm in Expression (1) to Expression (3).

The length of the vibration arm parts 12a, 12b together with the respective weight parts 16a, 16b means the sum of the length of the vibration arm part 12a and the length of the weight part 16a or the sum of the length of the vibration arm part 12b and the length of the weight part 16b, and the both are equivalent. The width of the weight parts 16a, 16b means the width of the weight part 16a or the width of the weight part 16b, and the both are equivalent.

Assuming that the “length” is a variable, the “length” is proportional to an area (length×width) when the “width” is a constant, and the “length” is proportional to a volume (length×width×thickness) when the “width” and the “thickness” are constants. Similarly, assuming that the “width” is a variable, the “width” is proportional to an area (width×length) when the “length” is a constant, and the “width” is proportional to a volume (width×length×thickness) when the “length” and the “thickness” are constants. In this case, Expressions (1) and (2) can be rewritten by taking the length (x and y) as an area or a volume.

Further, it is preferable that center lines 17a, 17b of the vibration arm parts 12a, 12b in the longitudinal direction (Y′-axis direction) coincide with the center lines 17a, 17b of the weight parts 16a, 16b in the longitudinal direction (Y′-axis direction), respectively. That is, it is preferable that the center line 17a of the vibration arm part 12a coincides with the center line 17a of the weight part 16a, and the center line 17b of the vibration arm part 12b coincides with the center line 17b of the weight part 16b. This is because secondary vibration is hardly generated when the principal vibration transmits from the vibration arm parts 12a, 12b to the weight parts 16a, 16b.

As shown in FIG. 2B, a piezoelectric device 30 according to the exemplary embodiment includes the tuning fork element 10 according to the exemplary embodiment mounted thereon. The piezoelectric device 30 can exhibit the same effect as that of the tuning fork element 10 through having the tuning fork element 10 mounted thereon.

Next, structures of the tuning fork element 10 will be described in more details.

In addition to the structural components described above, the tuning fork element 10 also includes: a protrusion 13 projected in the longitudinal direction (Y′-axis direction) from the base part 11 between the vibration arm parts 12a and 12b; a slit 14 extended in the longitudinal direction (Y′-axis direction) from the base end side of the protrusion 13 toward the tip side thereof; and grooves 15a, 15b extended linearly in the vibration arm parts 12a, 12b from the base part 11 side thereof to the weight parts 16a, 16b side thereof.

Each of the vibration arm parts 12a, 12b is extended in a same direction from the base part 11, and the grooves 15a, 15b are extended along their extending direction. The respective weight parts 16a, 16b for adjusting frequencies are provided at the tips of the vibration arm parts 12a, 12b. A quartz crystal vibration piece 19 formed by wet-etching a quartz crystal includes the base part 11, the vibration arm parts 12a, 12b, the protrusion 13, the slit 14, and the weight parts 16a, 16b. In addition to the quartz crystal vibration piece 19, the tuning fork element 10 also includes: pad electrodes 21a, 21b (FIG. 1); excitation electrodes 22a, 22b (FIG. 2A); and metal films for adjusting frequencies, wiring patterns and the like, which are not shown.

The base part 11 is a flat plate in roughly a quadrangle shape on a plan view. The quartz crystal vibration piece 19 has a tuning fork shape in which the base part 11, the vibration arm parts 12a, 12b, the protrusion 13, and the weight parts 16a, 16b are integrated, and it is fabricated by deposition, photolithography, and wet etching.

Two each of the grooves 15a, 15b are provided on the top and back faces of the respective vibration arm parts 12a, 12b from the border with respect to the base part 11 toward the tips of the vibration arm parts 12a, 12b by being extended in a prescribed length in parallel to the longitudinal direction of the vibration arm parts 12a, 12b. While two each of the grooves 15a, 15b are provided on the top and back faces of the vibration arm part 12a and two each on the top and back faces of the vibration arm part 12b in the first exemplary embodiment, the number of the grooves are not specifically limited. For example, one each may be provided on the top and back faces of the vibration arm part 12a and one each on the top and back faces of the vibration arm part 12b or may be provided only on one of the faces. Respective etching suppression patterns may be provided inside the grooves 15a, 15b so as not to be etched through at the time of wet etching. The etching suppression pattern is a structure inside the grooves having a shape to suppress progression of the etching.

The vibration arm part 12a includes the excitation electrode 22a located on both side faces such that the planes opposing to each other with the quartz crystal interposed therebetween come to have a same polarity, and includes the excitation electrode 22b located on the inner side of the grooves 15a on the top and back faces. Similarly, the vibration arm part 12b includes the excitation electrode 22b located on both side faces such that the planes opposing to each other with the quartz crystal interposed therebetween come to have a same polarity, and includes the excitation electrode 22a located on the inner side of the grooves 15b on the top and back faces. Therefore, the excitation electrode 22a located on both side faces of the vibration arm part 12a and the excitation electrode 22b located inside the grooves 15a come to have different polarities from each other, and the excitation electrode 22b located on both side faces of the vibration arm part 12b and the excitation electrode 22a located inside the grooves 15b come to have different polarities from each other.

The pad electrodes 21a, 21b and the wiring patterns, not shown, are located on the base part 11, while the respective metal films for adjusting frequencies, not shown, are located on the weight parts 16a, 16b. One of the wiring patterns electrically connects the pad electrode 21a with the excitation electrode 22a and the other of the wiring patterns connects the pad electrode 21b with the excitation electrode 22b. That is, the pad electrode 21a and the excitation electrode 22a are electrically connected, the pad electrode 21b and the excitation electrode 22b are electrically connected, and the pad electrode 21a and the excitation electrode 22a are electrically insulated from the pad electrode 21b and the excitation electrode 22b.

As shown in FIG. 2B, the tuning fork element 10 is fixed in a cantilever manner to a pad electrode 33 on an element loading member 32 side and electrically connected thereto at the same time via the pad electrodes 21a, 21b (FIG. 1) and respective conductive adhesives 31. The element loading member 32 on which the tuning fork element 10 is mounted is sealed by a lid member 34 to form a piezoelectric device 30. As a sealing method thereof, gold tine sealing, electric welding, or molten glass is used, for example.

The crystal system of the quartz crystal is a trigonal system. The crystallographic axis going through the peak of the quartz crystal is defined as a Z-axis, three crystallographic axes connecting ridgelines within a plane perpendicular to the Z-axis are defined as X-axes, and a coordinate axis orthogonal to the X-axes and the Z-axis is defined as a Y-axis. Note here that the Y-axis and the Z-axis after rotating a coordinate system of those X-axis, Y-axis, and Z-axis about the X-axis in a range of ±5 degrees, for example, are defined as Y′-axis and Z′-axis, respectively. In the first exemplary embodiment in such case, the longitudinal direction of the two vibration arm parts 12a, 12b is the direction of the Y′-axis, and the lateral direction of the two vibration arm parts 12a, 12b is the direction of the X-axis.

Next, operations of the tuning fork element 10 will be described.

For achieving bending vibration of the tuning fork element 10, an alternate voltage is applied to the pad electrodes 21a, 21b. When a certain electric state after applying the alternate voltage is captured in an instant, the excitation electrodes 22b located in the grooves 15a on the top and back faces of the vibration arm part 12a come to have a plus potential, the excitation electrodes 22a located on both side faces of the vibration arm part 12a come to have a minus potential, and an electric field is generated from the plus electrode to the minus electrode. At this time, the excitation electrodes 22a located in the grooves 15b on the top and back faces of the vibration arm part 12b come to have a minus potential while the excitation electrodes 22b located on both side faces of the vibration arm part 12b come to have a plus potential, which are reversed polarities from those of the case of the vibration arm part 12a, and an electric field is generated from the plus electrode to the minus electrode. An expansion and contraction phenomenon occurs in the vibration arm parts 12a, 12b due to the electric fields generated by the alternate voltage, so that a bending vibration mode of a prescribed resonance frequency can be acquired.

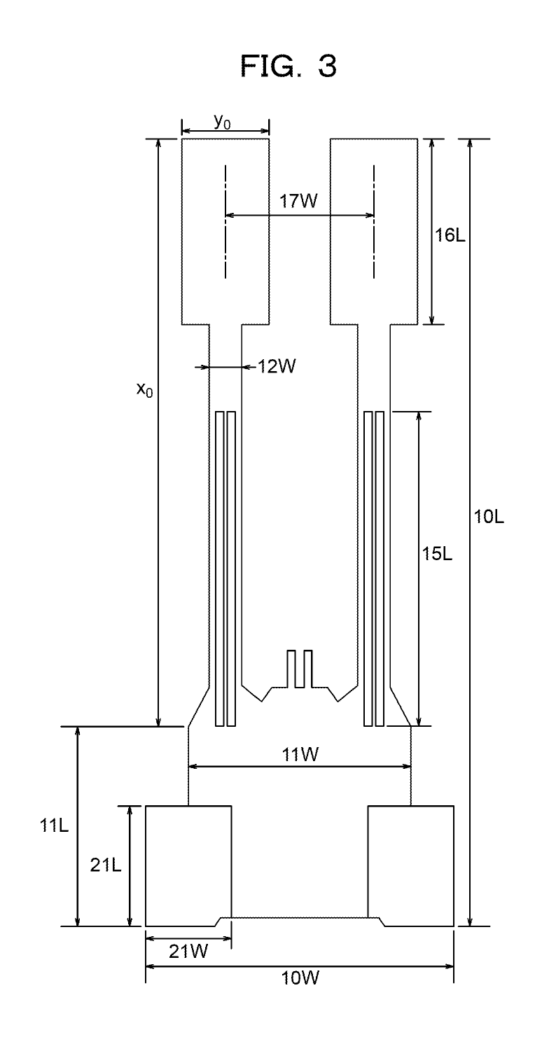

Next, examples of main measurements (unit is μm) of the tuning fork element 10 will be described by referring to FIG. 1 and FIG. 3.

Total length 10L of the tuning fork element 10=1052

Total width 10W of the tuning fork element 10=362

Length 11L of the base part 11=272

Width 11W of the base part 11=232

Length of the vibration arm parts 12a, 12b (reference value x₀)=780

Width 12W of the vibration arm parts 12a, 12b=40

Length 15L of the grooves 15a, 15b=420

Length 16L of the weight parts 16a, 16b=239

Width of the weight parts 16a, 16b (reference value y₀)=102

Width 17W between the center lines 17a and 17b=144.5

Length 21L of the pad electrodes 21a, 21b=160

Width 21W of the pad electrodes 21a, 21b=100

Thickness 19t of the quartz crystal vibration piece 19 (FIG. 2A)=100

Next, the simulation experiments of the tuning fork element 10 will be described.

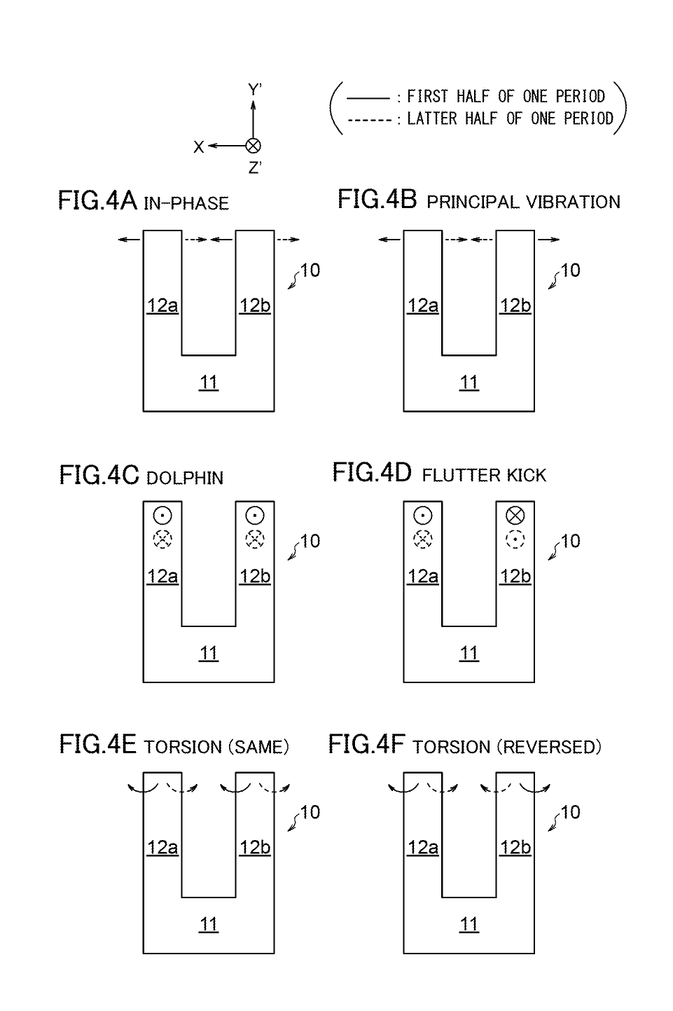

First, vibration modes of the tuning fork element 10 will be described. In each drawing of FIGS. 4A to 4F, the weight parts are omitted, solid-line arrows show movement in a first half of one period, and broken-line arrows show movement in a latter half of the one period.

The vibration mode shown in FIG. 4A is a mode in which the vibration arm parts 12a, 12b are in a same phase with respect to each other and vibrate in the ±X-axis directions, which is called herein as “in-phase”. The vibration mode shown in FIG. 4B is a mode in which the vibration arm parts 12a, 12b are in reversed phases with respect to each other and vibrate in the ±X-axis directions, which is called herein as “principal vibration”.

The vibration mode shown in FIG. 4C is a mode in which the vibration arm parts 12a, 12b are in a same phase with respect to each other and vibrate in ±Z′-axis directions, which is called herein as “dolphin” since it is similar to a dolphin kick of the butterfly stroke in swimming so to speak. The vibration mode shown in FIG. 4D is a mode in which the vibration arm parts 12a, 12b are in reversed phases with respect to each other and vibrate in ±Z′-axis directions, which is called herein as “flutter kick” since it is similar to a flutter kick of the crawl stroke in swimming so to speak.

The vibration mode shown in FIG. 4E is a mode in which the principal face of the vibration arm part 12a and the principal face of the vibration arm part 12b are in a same phase with respect to each other and vibrate torsionally to face the ±X-axis directions, which is called herein as “torsion (same)”. The vibration mode shown in FIG. 4F is a mode in which the principal faces of the vibration arm parts 12a, 12b are in reversed phases with respect to each other and vibrate torsionally to face the ±X-axis directions, which is called herein as “torsion (reversed)”. The “principal face” is a plane having the Z′-axis direction as its normal.

Further, harmonics for a fundamental wave are generally referred to as “2nd”. The change in the oscillation frequency before and after being mounted is referred to as “free-fix” which indicates a difference between a state before being mounted (free) and a state after being mounted (fix). A frequency difference between “principal vibration” and “in-phase” is defined as “in-phase difference”, i.e., “principal vibration”−“in-phase”=“in-phase difference”.

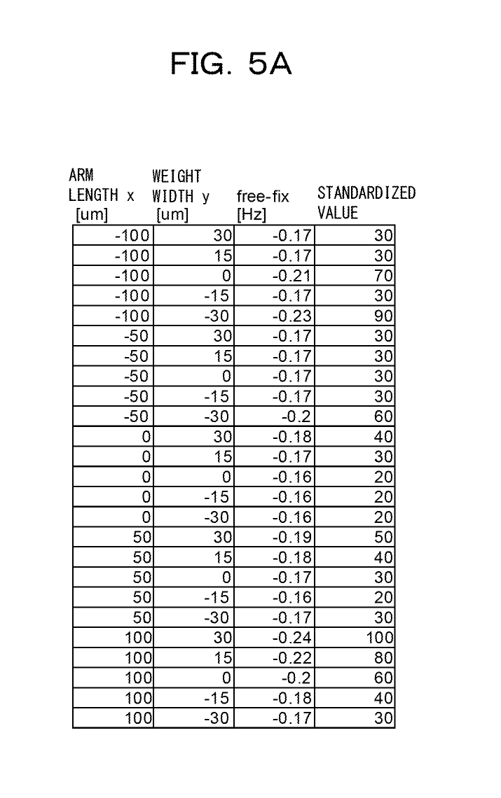

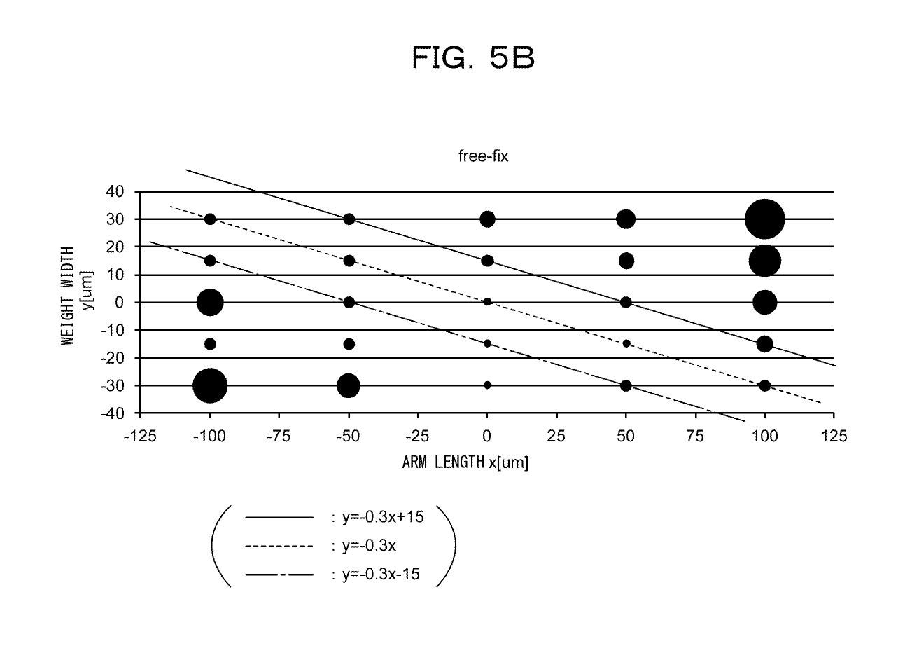

FIG. 5A to FIG. 11C show the results of the simulation experiments conducted with the tuning fork element 10 employing each of the measurements shown in FIG. 3. Hereinafter, a difference x between the length of the vibration arm parts 12a, 12b together with the respective weight parts 16a, 16b and the reference value x₀ is referred to as “arm length”, and a difference y between the width of the weight parts 16a, 16b and the reference value y₀ is referred to as “weight width”.

In the simulations, the arm length x was changed to −100, −50, 0, +50, +100, the weight width y was changed to −30, −15, 0, +15, +30, and “in-phase”, “principal vibration”, “dolphin”, “flutter kick”, “torsion (reversed)”, “torsion (same)”, “2nd”, “free”, “free-fix”, and “in-phase difference” were calculated for all the combinations of those values. Note that “free” is a frequency of the principal vibration before being mounted. The frequencies in each of the vibration modes are value after being mounted (fix). The oscillation frequency is 33.5 to 34 kHz. This oscillation frequency is a value before forming the metal films for adjusting frequencies on the weight parts 16a, 16b. In practice, after forming the metal films for adjusting frequencies on the weight parts 16a, 16b and mounting the tuning fork element 10 on the element loading member 32, the metal films for adjusting frequencies are etched to adjust the oscillation frequency to 32.768 kHz. Note that increase and decrease of the “free-fix” is increase and decrease of the absolute value thereof.

FIG. 5A is a table showing the fee-fix when the arm length x and the weight width y are changed. FIG. 5B is a graph showing the relations regarding the arm length x, the weight width y, and the free-fix. In FIG. 5A, “standardized values” can be acquired from following Expression (4).

Standardized value=(free-fix)×(−1000)−140 (4)

The diameters of the circles shown in FIG. 5B correspond to the standardized values shown in FIG. 5A.

As can be seen from FIG. 5B, it is found that the free-fix decreases when the arm length x and the weight width y satisfy following Expression (1).

−100≤x≤100,

−30≤y≤30, and

−0.3x−15≤y≤−0.3x+15 (1)

Further, it is found that the free-fix decreases more when the arm length x and the weight width y satisfy following Expression (2).

−100≤x≤100,

−30≤y≤30, and

y×−0.3x (2)

That is, in FIG. 5B, in a region sandwiched by a solid straight line y=−0.3x+15 and an alternate long-and-short dash line y=−0.3x−15, more preferably in a region on a broken straight line y=−0.3x, the diameters of the circles are small. Therefore, with the tuning fork element 10, changes in the oscillation frequency before and after being mounted can be decreased through improving the relation between the length of the vibration arm parts 12a, 12b together with the respective weight parts 16a, 16b and the width of the weight parts 16a, 16b.

Further, it is found that the free-fix can be decreased still more through narrowing the arm length x and the weight width y in Expression (1) or Expression (2) to the range shown in following Expression (3).

−50≤x≤50, and −15≤y≤15 (3)

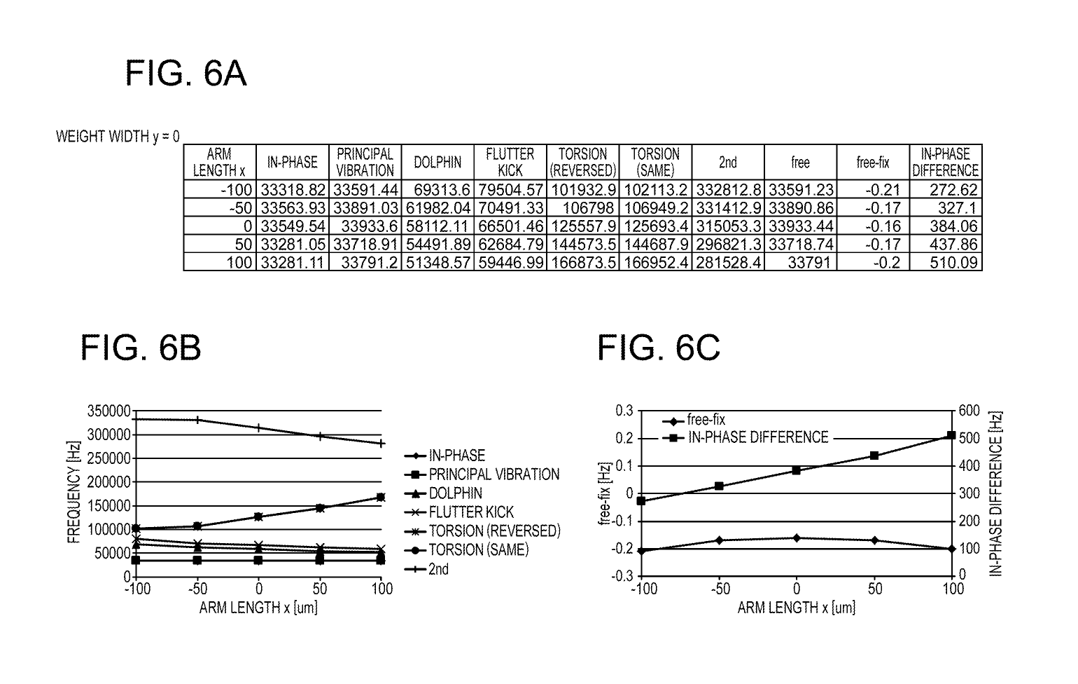

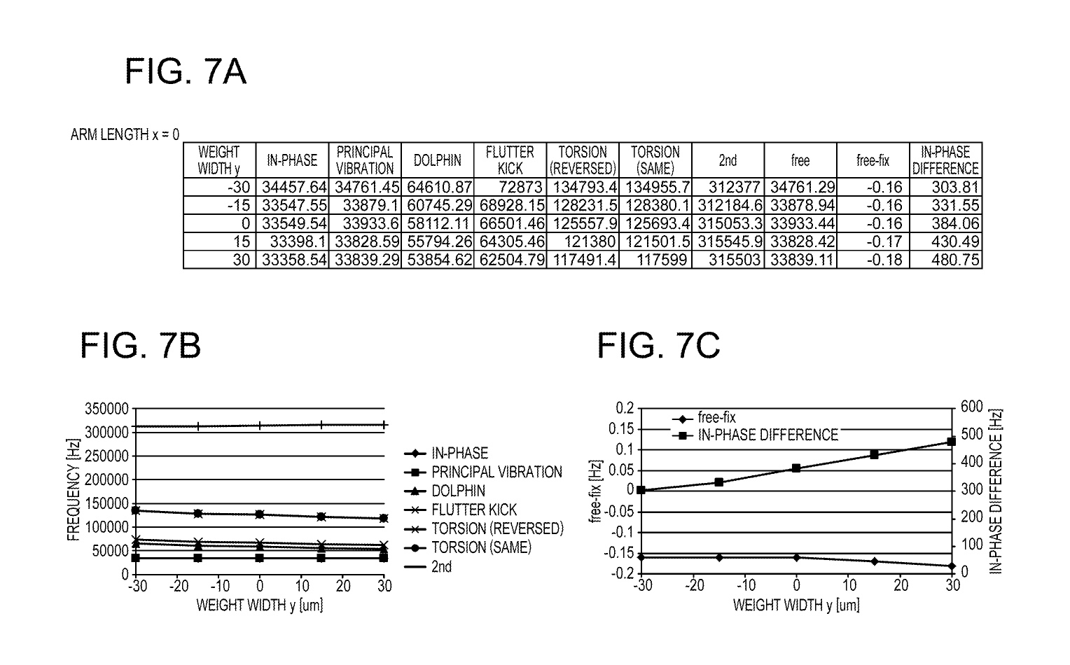

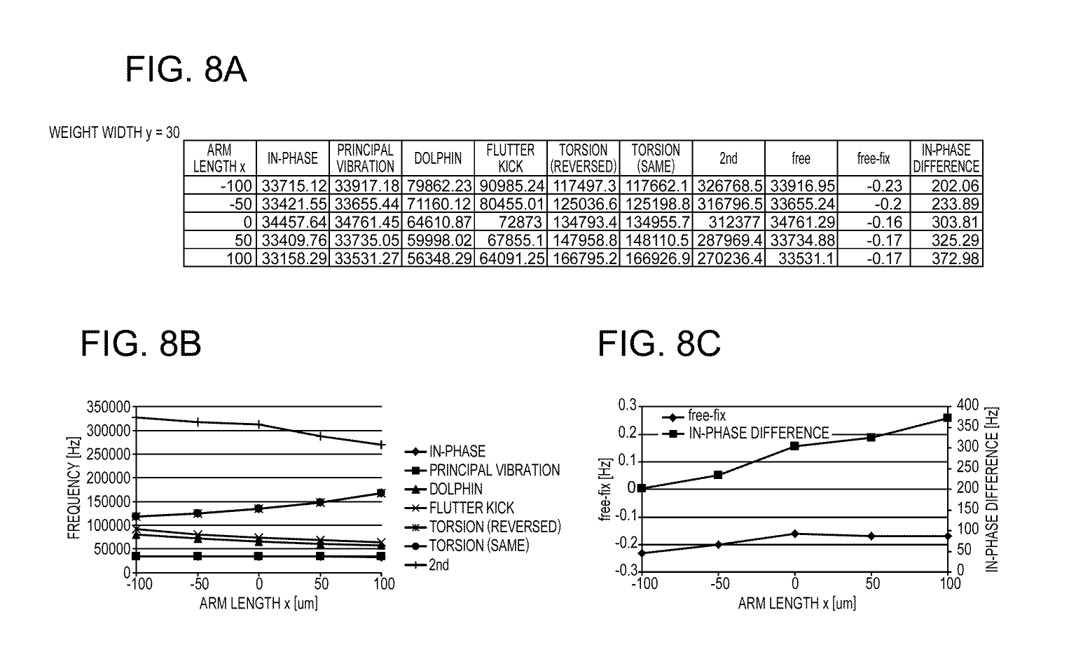

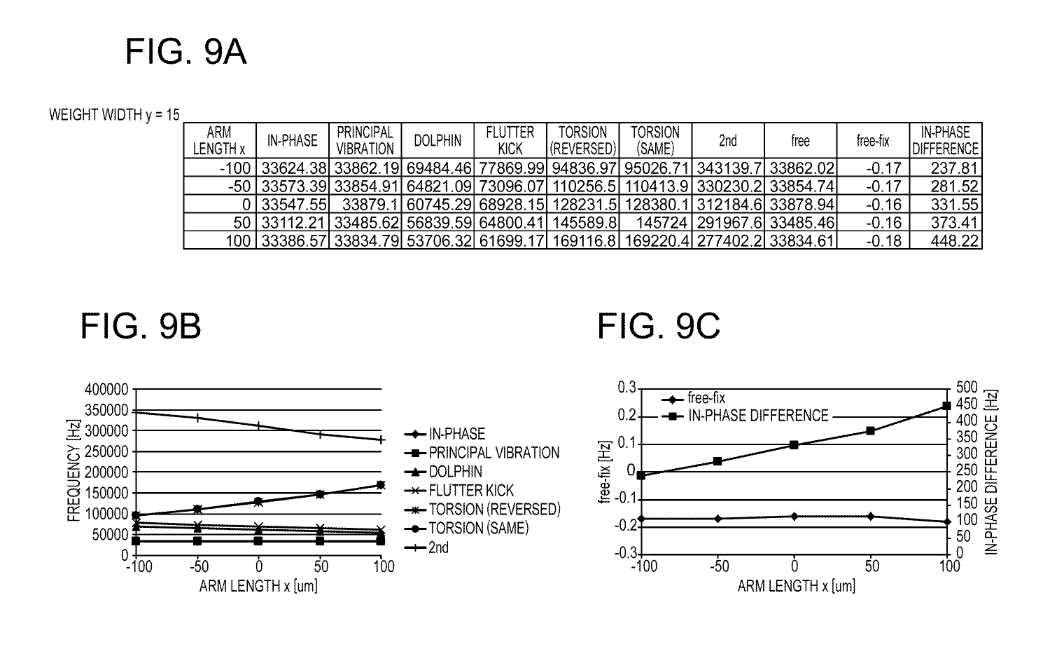

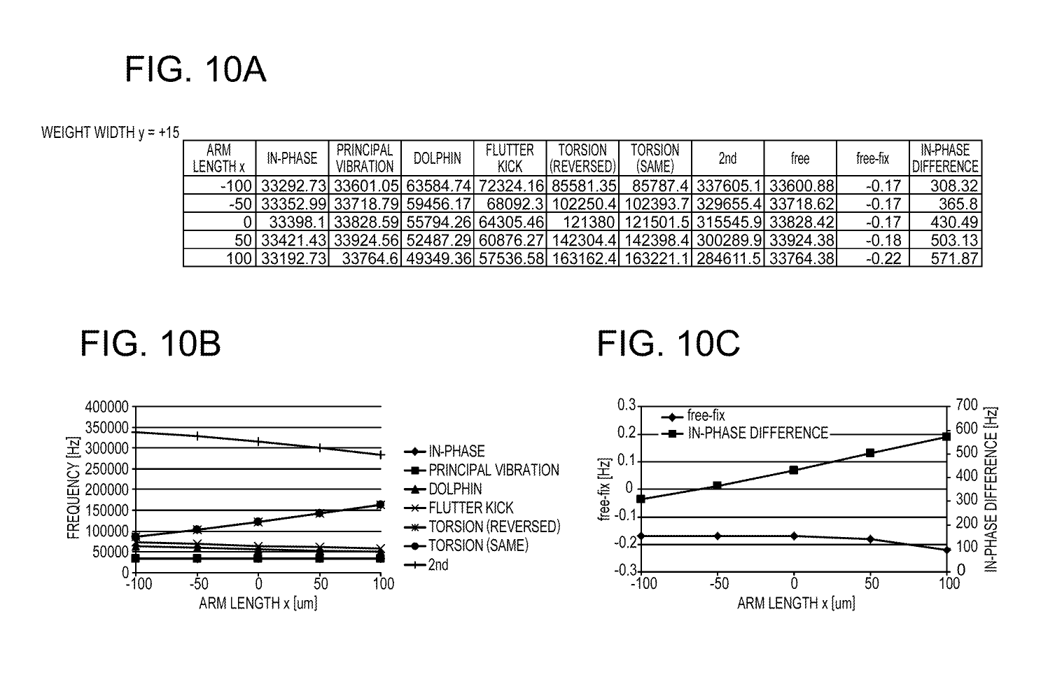

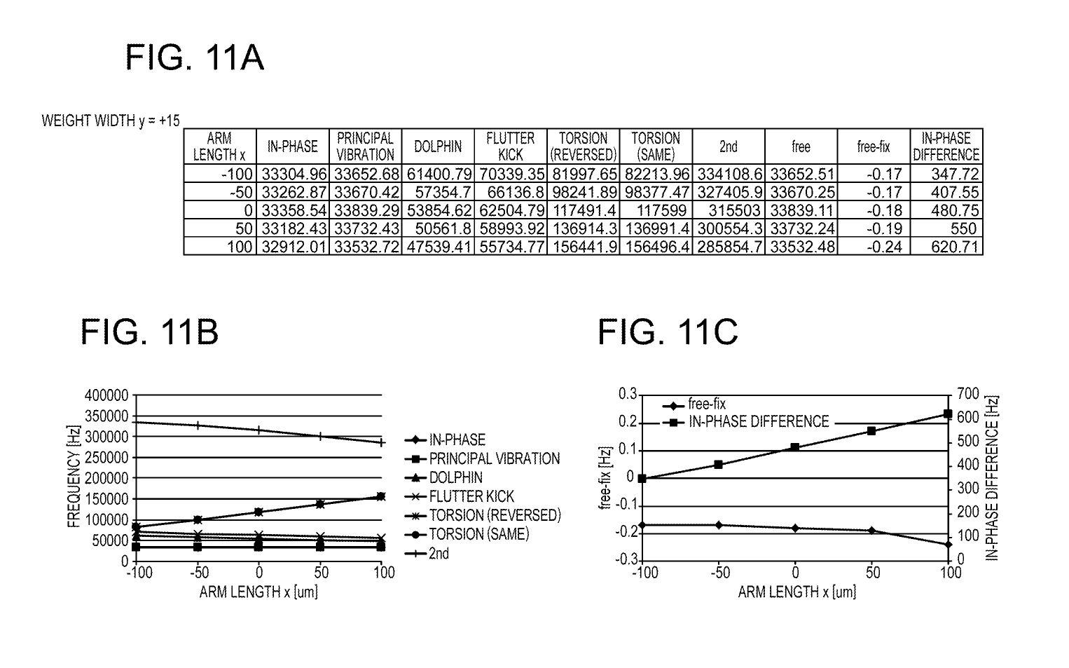

FIG. 6A to FIG. 6C show a case where the weight width y is fixed as 0 and the arm length x is changed, FIG. 7A to FIG. 7C show a case where the arm length x is fixed as 0 and the weight width y is changed, FIG. 8A to FIG. 8C show a case where the weight width y is fixed as −30 and the arm length x is changed, FIG. 9A to FIG. 9C show a case where the weight width y is fixed as −15 and the arm length x is changed, FIG. 10A to FIG. 10C show a case where the weight width y is fixed as +15 and the arm length x is changed, and FIG. 11A to FIG. 11C show a case where the weight width y is fixed as +30 and the arm length x is changed. The in-phase in FIG. 6B, FIG. 7B, FIG. 8B, FIG. 9B, FIG. 10B, and FIG. 11B is shown by overlapping with the principal vibration, so that it is shown as the in-phase difference in FIG. 6C, FIG. 7C, FIG. 8C, FIG. 9C, FIG. 10C, and FIG. 11C, respectively, by expanding the vertical axis.

As will be described hereinafter, there is a tendency recognized in FIG. 6A to FIG. 11C that the free-fix becomes increased as the frequency of a specific secondary vibration becomes closer to the frequency of the principal vibration.

FIG. 6A to FIG. 6C show the case where the weight width y is fixed as 0. The free-fix becomes increased as mainly the torsion (reversed) and the torsion (same) become closer to the principal vibration in a case where the arm length x is −100, and the free-fix becomes increased as mainly the dolphin and the flutter kick become closer to the principal vibration in a case where the arm length x is +100.

FIG. 7A to FIG. 7C show the case where the arm length x is fixed as 0. The free-fix becomes increased as mainly the torsion (reversed) and the torsion (same) become closer to the principal vibration in a case where the weight width y is +30.

FIG. 8A to FIG. 8C show the case where the weight width y is fixed as −30. The free-fix becomes increased as mainly the torsion (reversed) and the torsion (same) become closer to the principal vibration in a case where the arm length x is −100 and −50.

FIG. 9A to FIG. 9C show the case where the weight width y is fixed as −15. The free-fix is decreased generally regardless of the arm length x.

FIG. 10A to FIG. 10C show the case where the weight width y is fixed as +15. The free-fix becomes increased when mainly the dolphin and the flutter kick become closer to the principal vibration in a case where the arm length x is +100 and +50.

FIG. 11A to FIG. 11C show the case where the weight width y is fixed as +30. The free-fix becomes increased when mainly the dolphin and the flutter kick become closer to the principal vibration in a case where the arm length x is +100, +50, and 0.

While the present disclosure has been described by referring to the above exemplary embodiment, the present disclosure is not limited only to the exemplary embodiment described above. Various kinds of changes and modifications occurred to those skilled in the art can be applied to the structures and details of the present disclosure without departing from the scope of the appended claims. Further, the present disclosure also includes those acquired by applying such changes and modifications.

The present disclosure can be applied to any kinds of tuning fork elements that include a base part, vibration arm parts, and weight parts.

What is claimed is:

1. A tuning-fork type quartz crystal vibrating element, comprising:
a base part;
a pair of vibration arm parts extended in a same longitudinal direction from the base part; and
respective weight parts located at tips of the vibration arm parts, wherein
provided that, on a plan view, a measurement in the longitudinal direction is defined as length, a measurement in a direction perpendicular to the longitudinal direction is defined as width, a reference value of the length of the vibration arm parts together with the respective weight parts is defined as x₀, and a reference value of the width of the weight parts is defined as y₀,
following Expression (1) applies, where a difference between the length of the vibration arm parts together with the respective weight parts and the reference value x₀ is x, a difference between the width of the weight parts and the reference value y₀ is y, and a unit is μm:
−100≤x≤100,
−30≤y≤30, and
−0.3x−15≤y≤−0.3x+15 (1).

2. A tuning-fork type quartz crystal vibrating element, comprising:
a base part;
a pair of vibration arm parts extended in a same longitudinal direction from the base part; and
respective weight parts located at tips of the vibration arm parts, wherein
provided that, on a plan view, a measurement in the longitudinal direction is defined as length, a measurement in a direction perpendicular to the longitudinal direction is defined as width, a reference value of the length of the vibration arm parts together with the respective weight parts is defined as x₀, and a reference value of the width of the weight parts is defined as y₀,
following Expression (2) applies, where a difference between the length of the vibration arm parts together with the respective weight parts and the reference value x₀ is x, a difference between the width of the weight parts and the reference value y₀ is y, and a unit is μm:
−100≤x≤100,
−30≤y≤30, and
y=−0.3x (2).

3. The tuning-fork type quartz crystal vibrating element as claimed in claim 1, wherein the x and the y satisfy following Expression (3):
−50≤x≤50, and −15≤y≤15 (3).

4. The tuning-fork type quartz crystal vibrating element as claimed in claim 2, wherein the x and the y satisfy following Expression (3):
−50≤x≤50, and −15≤y≤15 (3).

5. The tuning-fork type quartz crystal vibrating element as claimed in claim 1, wherein the reference value x₀ is 780 μm and the reference value y₀ is 102 μm.

6. The tuning-fork type quartz crystal vibrating element as claimed in claim 2, wherein the reference value x₀ is 780 μm and the reference value y₀ is 102 μm.

7. The tuning-fork type quartz crystal vibrating element as claimed in claim 1, wherein center lines in the longitudinal direction of the vibration arm parts coincide with center lines in the longitudinal direction of the weight parts.

8. The tuning-fork type quartz crystal vibrating element as claimed in claim 2, wherein center lines in the longitudinal direction of the vibration arm parts coincide with center lines in the longitudinal direction of the weight parts.

9. A piezoelectric device, comprising the tuning-fork type quartz crystal vibrating element of claim 1 mounted thereon.

10. A piezoelectric device, comprising the tuning-fork type quartz crystal vibrating element of claim 2 mounted thereon.
